(19) United States
(12) Patent Application Publication
(10) Pub. No.: US 2025/0391675 A1
(43) Pub. Date: Dec. 25, 2025

(54) SUBSTRATE TREATING APPARATUS AND METHOD

(71) Applicant: SEMES CO., LTD., Cheonan-si (KR)

(72) Inventors: Hyun Woo BAE, Seoul (KR); Dae Hun KIM, Pyeongtaek-si (KR); Seung Eun NA, Bucheon-si (KR); Seong Hyeon KIM, Cheonan-si (KR); Dong Geon LEE, Seoul (KR); Sang Woo PARK, Pyeongtaek-si (KR); Ji Su HONG, Asan-si (KR); Seong Soo LEE, Yongin-si (KR)

(73) Assignee: SEMES CO., LTD., Cheonan-si (KR)

(21) Appl. No.: 19/244,057

(22) Filed: Jun. 20, 2025

(30) Foreign Application Priority Data
Jun. 20, 2024 (KR) 10-2024-0080512

(51) Int. Cl. H01L 21/67; B08B 9/032; H01L 21/02

(52) U.S. Cl. CPC H01L 21/67051; B08B 9/032; H01L 21/02057; B08B 2209/032

(57) ABSTRACT

Disclosed is a method of treating a substrate, the method including: a nozzle moving operation of moving a nozzle unit having a first flow path and a second flow path to a top of a substrate; a first discharge operation of, after the nozzle moving operation, discharging a first treatment liquid to the substrate through the first flow path; and a second discharge operation of, after the first discharge operation, stopping the discharge of the first treatment liquid to the substrate through the first flow path, sucking back the first flow path, and simultaneously discharging a second treatment liquid to the substrate through the second flow path.

### CROSS-REFERENCE TO RELATED APPLICATIONS

This application claims priority to and the benefit of Korean Patent Application No. 10-2024-0080512 filed in the Korean Intellectual Property Office on Jun. 20, 2024, the entire contents of which are incorporated herein by reference.

### TECHNICAL FIELD

The present invention relates to a substrate treating apparatus and method, and more particularly, to a substrate treating apparatus and method for treating a substrate by supplying a plurality of treatment liquids to the substrate.

### BACKGROUND ART

A semiconductor process includes a process of cleaning a thin film, foreign substances, particles, and the like on a substrate. These processes are performed by placing the substrate on a spin head so that a pattern side faces up or down, supplying a treatment liquid to the substrate while rotating the spin head, and then drying the wafer.

When a treatment liquid is supplied onto a substrate, a plurality of treatment liquids may be supplied by one single nozzle. Furthermore, when a mixing space is formed inside a single nozzle, a plurality of treatment liquids are simultaneously supplied to the mixing space, allowing the single nozzle to discharge a mixture of the plurality of treatment liquids.

When the discharge of the mixed liquid is completed, a part of the mixed liquid remains in the mixing space. When some of the plurality of treatment liquids are supplied at a high temperature, the high-temperature mixed liquid may remain in the mixing space. The high-temperature residual mixed liquid may have the following problems. First, the high-temperature residual mixed liquid may have bubbles formed therein due to the high temperature. Bubbles may increase the discharge pressure when discharging the treatment liquid in a subsequent process operation, causing non-uniform discharge of the treatment liquid, and may damage the pattern formed on the substrate. In addition, the single treatment liquid subsequently discharged due to the mixed liquid is supplied to the substrate at a temperature higher than a set temperature, thereby degrading the uniformity of the process.

### SUMMARY OF THE INVENTION

The present invention has been made in an effort to provide a substrate treating apparatus and method capable of improving the uniformity of processes between substrates when treating a substrate while discharging a next treatment liquid after discharging a high-temperature treatment liquid.

The present invention has also been made in an effort to provide a substrate treating apparatus and method that is capable of preventing damage to the substrate when a next treatment liquid is discharged after discharging a high-temperature treatment liquid.

The present invention has also been made in an effort to provide a substrate treating apparatus and method that is capable of discharging a next treatment liquid after discharging a high-temperature treatment liquid while maintaining a uniform temperature.

The present invention has also been made in an effort to provide a substrate treating apparatus and method that is capable of facilitate the maintenance and management of a treatment liquid supply unit.

The objectives of the present disclosure are not limited thereto and other objectives not stated herein may be clearly understood by those skilled in the art from the following description.

An exemplary embodiment of the present invention, a method of treating a substrate, the method comprising may include, a nozzle moving operation of moving a nozzle unit having a first flow path and a second flow path to a top of a substrate; a first discharge operation of, after the nozzle moving operation, discharging a first treatment liquid to the substrate through the first flow path; and a second discharge operation of, after the first discharge operation, stopping the discharge of the first treatment liquid to the substrate through the first flow path, sucking back the first flow path, and simultaneously discharging a second treatment liquid to the substrate through the second flow path.

According to the exemplary embodiment of the present invention, in the first discharge operation, an impact point of the first treatment liquid is a center of the substrate, and at a start of the second discharge operation, an impact point of the second treatment liquid may be a position off the center of the substrate.

According to the exemplary embodiment of the present invention, the second discharge operation may include: a moving discharge operation of discharging the second treatment liquid while moving the impact point of the second treatment liquid to the center of the substrate; and a fixed discharge operation of discharging the second treatment liquid by fixing the impact point of the second treatment liquid to the center of the substrate after the moving discharge operation.

According to the exemplary embodiment of the present invention, the apparatus may further include a cleaning operation of, after the second discharge operation, cleaning the first treatment liquid remaining in the first flow path.

According to the exemplary embodiment of the present invention, the cleaning operation includes supplying the cleaning solution to the first flow path in a state in which the second flow path may be sucked back.

According to the exemplary embodiment of the present invention, the cleaning solution may be the second treatment liquid.

According to the exemplary embodiment of the present invention, the first treatment liquid may include sulfuric acid, and the second treatment liquid contains hydrogen peroxide solution.

According to the exemplary embodiment of the present invention, the cleaning operation may be performed at a home port where the nozzle unit waits.

According to the exemplary embodiment of the present invention, the nozzle unit may include: a first nozzle in which the first flow path is formed; a second nozzle in which the second flow path is formed; a nozzle arm equipped with the first nozzle and the second nozzle; and an arm driver for moving the nozzle arm.

According to the exemplary embodiment of the present invention, the nozzle unit may include a single nozzle in which the first flow path and the second flow path are formed.

An exemplary embodiment of the present invention, an apparatus for treating a substrate, the apparatus comprising: a housing providing an interior space; a cup body for providing a treatment space for treating a substrate in the interior space; a support unit for supporting a substrate in the treatment space; a treatment liquid supply unit for supplying a treatment liquid to a substrate supported by the support unit; and a nozzle unit having a first flow path and a second flow path; and a controller for controlling the treatment liquid supply unit, wherein the treatment liquid supply unit includes: a first treatment liquid supply source for storing a first treatment liquid; a second treatment liquid supply source for storing a second treatment liquid; a mixing member for mixing the first treatment liquid and the second treatment liquid; a first opening/closing valve provided in a path through which the first treatment liquid is supplied to the first flow path; a second opening/closing valve provided in a path through which the second treatment liquid is supplied to the second flow path; a first suck-back valve for sucking back the first flow path; and a controller for controlling the treatment liquid supply unit, and the controller may controls the first opening/closing valve, the first suck-back valve, and the second opening/closing valve so as to discharge the first treatment liquid to the substrate through the first flow path after moving the nozzle unit to a top of the substrate, stop the discharge of the first treatment liquid to the substrate through the first flow path and suck back the first flow path after the discharge of the first treatment liquid, and simultaneously discharge the second treatment liquid to the substrate through the second flow path.

According to the exemplary embodiment of the present invention, an impact point of the first treatment liquid is a center of the substrate, and at a start of the discharge of the second treatment liquid, an impact point is a position off the center of the substrate, and the controller may controls the treatment liquid supply unit to move the impact point of the second treatment liquid to the center of the substrate while discharging the second treatment liquid and fix the impact point of the second treatment liquid to the center of the substrate.

According to the exemplary embodiment of the present invention, the treatment liquid supply unit includes a second suck-back valve for sucking back the second flow path, the apparatus further comprises a home port where the nozzle waits, and the controller may controls the treatment liquid supply unit to stop supplying the second treatment liquid before the nozzle moves to the home port, to suck back the second flow path, and to clean the first treatment liquid remaining in the first flow path of the nozzle unit after the nozzle moves to the home port.

According to the exemplary embodiment of the present invention, the controller may controls the treatment liquid supply unit to clean the first flow path with the second treatment liquid.

According to the exemplary embodiment of the present invention, the nozzle unit may include: a first nozzle in which the first flow path is formed; a second nozzle in which the second flow path is formed; a nozzle arm equipped with the first nozzle and the second nozzle; and an arm driver for moving the nozzle arm.

According to the exemplary embodiment of the present invention, the nozzle unit may include a single nozzle in which the first flow path and the second flow path are formed.

According to the exemplary embodiment of the present invention, the first treatment liquid may include sulfuric acid, and the second treatment liquid contains hydrogen peroxide solution.

An exemplary embodiment of the present invention, a method of treating a substrate, the method comprising: a nozzle moving operation of moving a nozzle unit having a first flow path and a second flow path to a top of a substrate; a first discharge operation of, after the nozzle moving operation, discharging a first treatment liquid in which sulfuric acid is mixed with hydrogen peroxide solution to the substrate through the first flow path; a second discharge operation of, after the first discharge operation, stopping the discharge of the first treatment liquid to the substrate through the first flow path, sucking back the first flow path, and simultaneously discharging a second treatment liquid, which is hydrogen peroxide solution, to the substrate through the second flow path; and a cleaning operation of, after the second discharge operation, cleaning the first treatment liquid remaining in the first flow path, in the first discharge operation, an impact point of the first treatment liquid is a center of the substrate, and at a start of the second discharge operation, an impact point of the second treatment liquid is a position off the center of the substrate, and the second discharge operation may include, a moving discharge operation of discharging the second treatment liquid while moving the impact point of the second treatment liquid to the center of the substrate; and a fixed discharge operation of discharging the second treatment liquid by fixing the impact point of the second treatment liquid to the center of the substrate after the moving discharge operation.

According to the exemplary embodiment of the present invention, the cleaning operation includes discharging the second treatment liquid through the first flow path in a state where the nozzle unit is moved to a waiting home port, and the second flow path may be sucked back.

According to the exemplary embodiment of the present invention, the nozzle unit may include a single nozzle in which the first flow path and the second flow path are formed.

According to the exemplary embodiment of the present invention, uniformity of processes between substrates may be improved when the substrate is treated while discharging a next treatment liquid after discharging a high-temperature treatment liquid.

Further, according to the exemplary embodiment of the present invention, it is possible to prevent damage to the substrate when a next treatment liquid is discharged after discharging a treatment liquid at a high temperature.

Further, according to the exemplary embodiment of the present invention, when a next treatment liquid is discharged after discharging a high-temperature treatment liquid, the treatment liquid may be discharged while maintaining a uniform temperature.

Further, according to the exemplary embodiment of the present invention, maintenance and management of a treatment liquid supply unit may be facilitated.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view schematically illustrating a substrate treating apparatus according to an exemplary embodiment of the present invention.

FIG. 2 is a diagram schematically illustrating an exemplary embodiment of a liquid treating chamber of FIG. 1.

FIG. 3 is a diagram schematically illustrating a treatment liquid supply unit according to an exemplary embodiment of the present invention.

FIG. 4 is a diagram schematically illustrating a nozzle of a nozzle unit according to an exemplary embodiment of the present invention.

FIG. 5 is a flowchart illustrating a substrate treating method according to an exemplary embodiment of the present invention.

FIG. 6 is a diagram schematically illustrating a moving discharge operation of FIG. 5.

FIG. 7 is a diagram schematically illustrating a first discharge operation of FIG. 5.

FIG. 8 is a diagram schematically illustrating a stop operation in a second discharge operation of FIG. 5.

FIG. 9 is a diagram schematically illustrating a suck-back operation and a discharge operation in the second discharge operation of FIG. 5.

FIG. 10 is a diagram schematically illustrating a moving discharge operation and a fixed discharge operation in the second discharge operation.

FIG. 11 is a diagram schematically illustrating a stop operation in a cleaning operation of FIG. 5.

FIG. 12 is a diagram schematically illustrating a suck-back operation and a cleaning operation in the cleaning operation of FIG. 5.

FIG. 13 is a diagram schematically illustrating a nozzle of a nozzle unit according to another exemplary embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

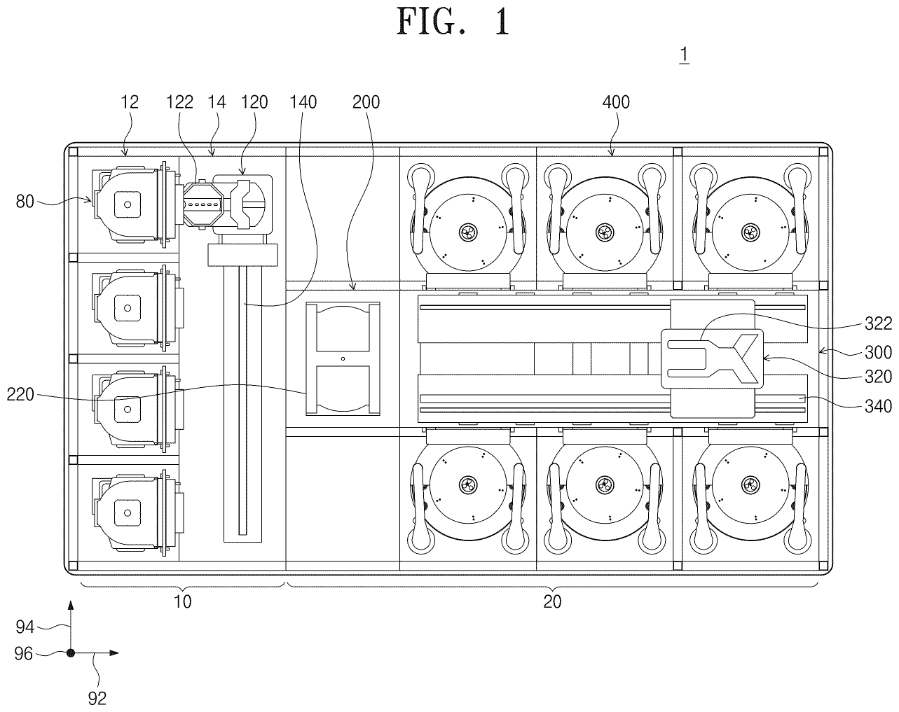

Hereinafter, exemplary embodiments of the present invention will be described with reference to the accompanying drawings. FIG. 1 is a top plan view schematically illustrating a substrate treating apparatus according to an exemplary embodiment of the present invention.

Referring to FIG. 1, a substrate treating apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forwardly and backwardly independently of each other.

The treating module 20 includes a buffer chamber 200, a transfer chamber 300, and a treating chamber 400. The buffer chamber 200 provides a space in which the substrate W loaded into the treating module 20 and the substrate W unloaded from the treating module 20 temporarily stay. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer chamber 200 may be disposed between the index module 10 and the transfer chamber 300. A plurality of liquid treatment chambers 400 is provided and may be disposed on the side of the transfer chamber 300. The liquid treatment chamber 400 and the transfer chamber 300 may be disposed in the second direction 94. The buffer chamber 200 may be positioned at one end of the transfer chamber 300.

According to the example, the liquid treatment chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer chamber 200 includes a plurality of buffers 220 on which the substrate W is temporarily placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer chamber 200 through the front surface, and the transfer robot 320 may access the buffer chamber 200 through the rear surface.

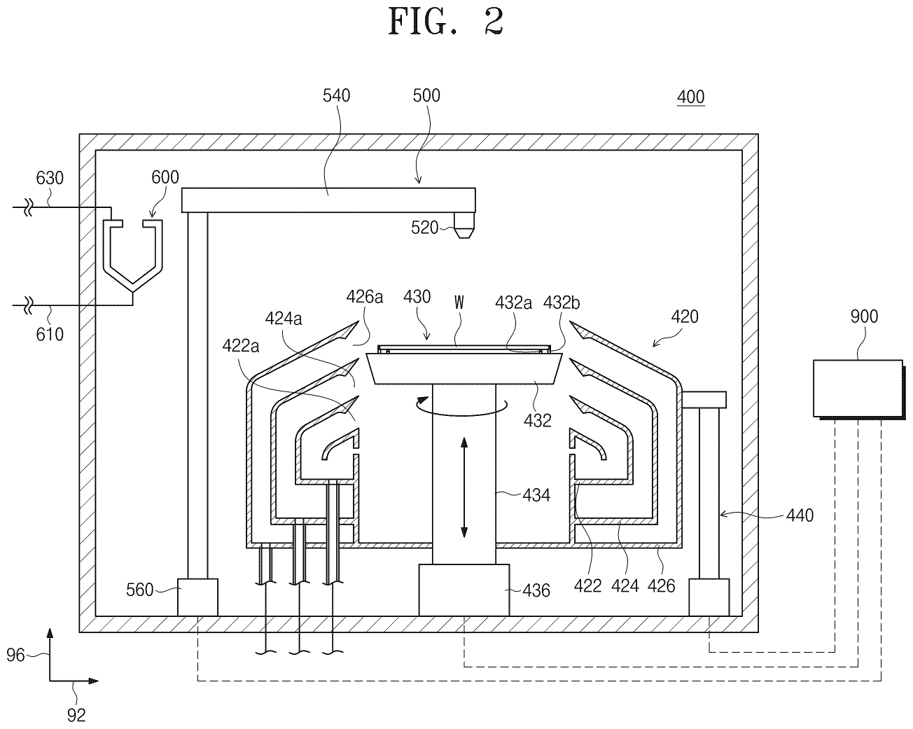

FIG. 2 is a diagram schematically illustrating the liquid treating chamber 400 of FIG. 1 according to the exemplary embodiment. Referring to FIG. 2, the liquid treating chamber 400 includes a housing 410, a cup body 420, a support unit 430, a lifting unit 440, a treatment liquid supply unit 450, a nozzle unit 500, a home port 600, and a controller 900.

The housing 410 is provided in a generally rectangular parallelepiped shape. The cup body 420, the support unit 430, and the liquid supply unit 440 are disposed within the housing 410.

The cup body 420 has a treatment space with an open top, and the substrate W is liquid-treated in the treatment space. The support unit 430 supports the substrate W in the treatment space. The liquid supply unit 440 supplies the liquid onto the substrate W supported by the support unit 430. The liquid may be provided in a plurality of types, and may be sequentially supplied onto the substrate W. The lifting unit 440 adjusts a relative height between the cup body 420 and the support unit 430.

According to the exemplary embodiment, the cup body 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 430. When the liquid treatment process is in progress, the treatment liquid scattered by the rotation of the substrate W is introduced into the recovery space through inlets 422a, 424a, and 426a of the respective recovery containers 422, 424, and 426. According to the exemplary embodiment, the cup body 420 has a first recovery container 422, a second recovery container 424, and a third recovery container 426. The first recovery container 422 is disposed to surround the support unit 430, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 2640 has a support plate 2642 and a drive shaft 430. An upper surface of the support plate 432 may be provided in a generally circular shape, and may have a diameter larger than a diameter of the substrate W. In the center portion of the support plate 432, a support pin 432a is provided to support the rear surface of the substrate W, and the support pin 432a is provided with its upper end protruding from the support plate 432 so that the substrate W is spaced apart from the support plate 432 by a certain distance. A chuck pin 432b is provided to an edge of the support plate 432. The chuck pin 432b is provided to protrude upwardly from the support plate 432, and supports the lateral portion of the substrate W so that the substrate W is not separated from the support unit 430 when the substrate W is rotated. A drive shaft 434 is driven by a driver 436, is connected to the center of the bottom surface of the substrate W, and rotates the support plate 432 with respect to the central axis thereof.

The lifting unit 440 moves the cup body 420 in the up and down direction. By the up and down movement of the cup body 420, a relative height between the cup body 420 and the substrate W is changed. Accordingly, since the recovery containers 422, 424, and 426 for recovering the treatment liquid are changed according to the type of the liquid supplied to the substrate W, the liquids may be separated and recovered. Unlike the above description, the cup body 420 is fixedly installed, and the lifting unit 440 may move the support unit 430 in the up and down direction.

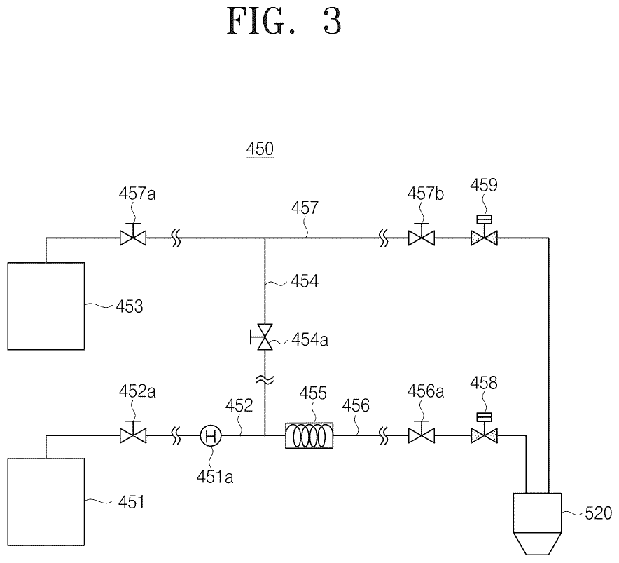

The treatment liquid supply unit 450 supplies the treatment liquid to the nozzle unit 500 to be described later. The treatment liquid may be a mixture of the first treatment liquid and the second treatment liquid (hereinafter, referred to as a “mixed liquid”) or a second treatment liquid. FIG. 3 is a diagram schematically illustrating the treatment liquid supply unit according to an exemplary embodiment of the present invention. Referring to FIG. 3, the treatment liquid supply unit 450 may include a first treatment liquid supply source 451, a first treatment liquid mixing line 452, a second treatment liquid supply source 453, a second treatment liquid mixing line 454, a mixing member 455, a mixed liquid supply line 456, a second treatment liquid supply line 457, a first suck-back valve 458, and a second suck-back valve 459.

The first treatment liquid supply source 451 stores the first treatment liquid. According to the example, the first treatment liquid may be a solution containing sulfuric acid (H₂SO₄). The first treatment liquid supply source 451 supplies the first treatment liquid to the first treatment liquid mixing line 452. The first treatment liquid mixing line 452 connects the first treatment liquid supply source 451 to the mixing member 455. A valve 452a is installed in the first treatment liquid mixing line 452. The valve 452a is provided as an open/close valve. Further, a heater 451may be installed on the first treatment liquid mixing line 452. The heater 451a heats the first treatment liquid at a constant temperature. According to the example, the heater 451a may be provided as a line heater.

The second treatment liquid supply source 453 stores the second treatment liquid. According to the example, the second treatment liquid may be hydrogen peroxide solution (H₂O₂). The second treatment liquid supply source 453 supplies the second treatment liquid to the second treatment liquid supply line 457. The second treatment liquid supply line 457 supplies the second treatment liquid to the nozzle unit 500. The valves 457a and 457b are installed in the second treatment liquid supply line 457. The valves 457a and 457b are provided as an open/close valve.

The valve 457a may be installed upstream of the second treatment liquid supply line 457. The valve 457a may be installed upstream from a branch point where the second treatment liquid mixing line 454 branches. The valve 457a may be installed adjacent to the second treatment liquid supply source 453. Accordingly, the valve 457a may determine whether to supply the second treatment liquid from the second treatment liquid supply source 453 to the second treatment liquid supply line 457.

The valve 457b may be installed downstream of the second treatment liquid supply line 457. The valve 457b may be installed downstream from a branch point where the second treatment liquid mixing line 454 branches. The valve 457b may be installed adjacent to the second suck-back valve 459. The valve 457b may be installed upstream from the second suck-back valve 459. Accordingly, the valve 457b may determine whether to supply the treatment liquid to a second flow path 524 of the nozzle 520.

Furthermore, the second suck-back valve 459 may be installed in the second treatment liquid supply line 457. The second suck-back valve 459 may be installed downstream of the second treatment liquid supply line 457. The second suck-back valve 459 may be installed adjacent to the valve 457b. The second suck-back valve 459 may be installed downstream from the valve 457b. The second suck-back valve 459 performs a suck-back of the second treatment liquid remaining in the second flow path 524 to be described later. Accordingly, it is possible to prevent the treatment liquid from falling from the second flow path 524 to the substrate W while the discharge of the treatment liquid from the second flow path 524 is stopped.

In the above example, the present invention has been described based on the case where the valve 457b and the second suck-back valve 459 are respectively provided as an example. However, the present invention is not limited thereto, and may be provided as a single valve unit having an opening/closing function and a suck-back function.

Also, the second treatment liquid mixing line 454 is branched from the second treatment liquid supply line 457. The second treatment liquid mixing line 454 supplies the second treatment liquid to the mixing member 455. A valve 454a is installed in the second treatment liquid mixing line 454. The valve 454a is provided as an open/close valve.

The mixing member 455 mixes the first treatment liquid and the second treatment liquid. According to the example, the mixing member 455 may be provided as an in-line mixer. The mixed solution may be a sulfonic acid peroxide mixture (SPM). The mixed solution mixed in the mixing member 455 is supplied to the nozzle unit 500 to be described later through the mixed solution supply line 456.

A valve 456a is installed in the mixed liquid supply line 456. The valve 456a may be installed downstream of the mixed liquid supply line 456. The valve 456a may be installed downstream from a confluence point where the second treatment liquid mixed line 454 joins. The valve 456a may be installed adjacent to the first suck-back valve 458. The valve 456a may be installed upstream from the first suck-back valve 458. Accordingly, the valve 456a may determine whether to supply the treatment liquid to the first flow path 522 of the nozzle 520.

Furthermore, a first suck-back valve 458 may be installed in the mixed liquid supply line 456. The first suck-back valve 458 may be installed downstream of the mixed liquid supply line 456. The first suck-back valve 458 may be installed adjacent to the valve 456a. The first suck-back valve 458 may be installed downstream of the valve 456a. The first suck-back valve 458 may suck-back the treatment liquid remaining in the first flow path 522 to be described later. Accordingly, it is possible to prevent the mixed liquid from falling from the first flow path 522 to the substrate W in a state where the mixed liquid is discharged from the first flow path 522 is stopped.

In the above-described example, the present invention has been described based on the case where the valve 456a and the first suck-back valve 458 are respectively provided as an example. However, the present invention is not limited thereto, and may be provided as a single valve unit having an opening/closing function and a suck-back function.

The nozzle unit 500 may include a nozzle 520, an arm 540, and a driver 560. The first flow path 522 and the second flow path 524 are formed inside the nozzle 520. One end of the first flow path 522 is connected to the mixed solution supply line 456. The other end of the first flow path 522 extends to the discharge end of the nozzle 520. One end of the second flow path 524 is connected to the second treatment liquid supply line 457. The other end of the second flow path 524 extends to the discharge end of the nozzle 520. Accordingly, the nozzle 520 may discharge the mixed solution and the second treatment liquid onto the substrate W. The nozzle 520 is supported by the arm 540. The arm 540 may be moved by the driver 560. Accordingly, the nozzle 520 may be moved.

Optionally, the nozzle unit 500 may further include one or a plurality of nozzles in addition to the nozzles 520. Additional nozzles may supply different types of treatment liquids to the substrate. For example, the other type of treatment liquid may be an acid solution or a base solution for removing foreign substances on the substrate. In addition, another type of treatment liquid may be alcohol having surface tension lower than that of water. For example, alcohol may be isopropyl alcohol (IPA).

The home port 600 makes the nozzle 520 stand by before or after the substrate W is treated. The home port 600 is located outside the cup body 420 in the interior space of the housing 410. A drainage line 610 is connected to a lower end of the home port 600. The drainage line 610 recovers the treatment liquid and the mixed liquid discharged from the nozzle 520. Also, an exhaust line 630 is connected to the home port 600. The exhaust line 630 exhausts gas, fumes, and the like generated from the nozzle 520, and the like. Also, a cleaning nozzle (not illustrated) for cleaning an outer wall of the nozzle 520 and a drying nozzle (not illustrated) for drying may be additionally provided in the home port 600.

The controller 900 may control each configuration of the substrate treating apparatus. The controller 900 may control the overall operation of the substrate treating apparatus. The controller 900 may include a Central Processing Unit (CPU), Read Only Memory (ROM), and Random Access Memory (RAM). The CPU executes desired processing, such as etching treatment according to various recipes stored in these storage areas. The recipe contains the device's control information for the process conditions. Meanwhile, the program or recipe representing the processing conditions may be stored in a non-transitory computer-readable medium. A non-transitory computer-readable medium means a medium that stores data on a semi-permanent basis and is readable by a computer, rather than a medium that stores data for a short period of time, such as a register, cache, memory, or the like. Specifically, the various applications or programs described above may be stored and provided on non-transitory readable media, such as CDs, DVDs, hard disks, Blu-ray discs, USBs, memory cards, or ROMs.

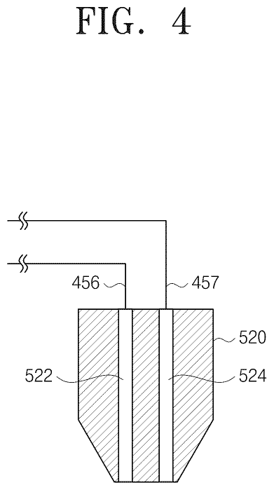

Hereinafter, a substrate treating method according to an exemplary embodiment will be described. The substrate treating method described below may be performed by the substrate treating apparatus described with reference to FIGS. 1 to 4. Accordingly, hereinafter, a substrate treating method according to an exemplary embodiment will be described by referring to reference numerals illustrated in FIGS. 1 to 4. Further, the substrate treating method described herein may be performed by the controller 900 controlling configurations included in the substrate treating apparatus described above.

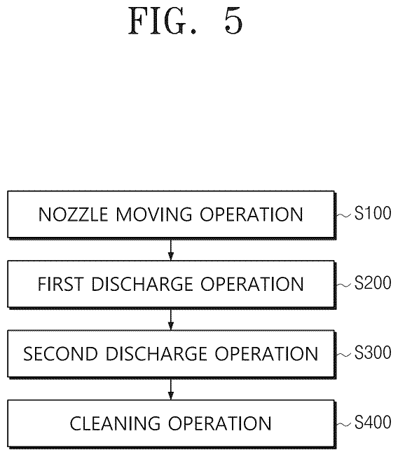

FIG. 5 is a flowchart illustrating a substrate treating method according to an exemplary embodiment of the present invention. Referring to FIG. 5, a substrate treating method includes a nozzle moving operation S100, a first discharge operation S200, a second discharge operation S300, and a cleaning operation S400.

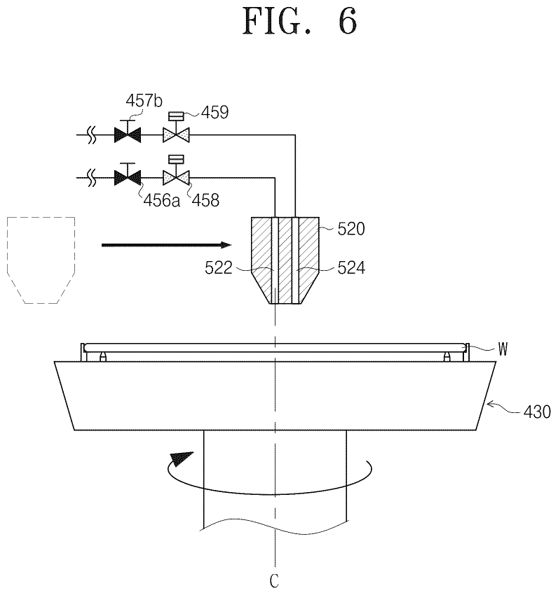

FIG. 6 is a diagram schematically illustrating a moving discharge operation of FIG. 5. Referring to FIG. 6, in the nozzle moving operation S100, the nozzle 520 is moved onto the substrate W by the driver 560. When viewed from above, the nozzle 520 is moved so that the center C of the substrate and the first flow path 522 overlap each other. Accordingly, when viewed from above, the second flow path 524 is positioned to be spaced apart from the center C of the substrate.

After the nozzle moving operation S100, the first discharge operation S200 may be performed.

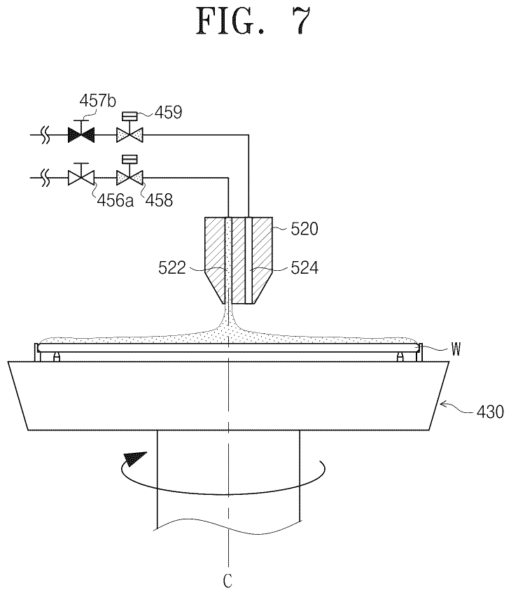

FIG. 7 is a diagram schematically illustrating the first discharge operation of FIG. 5. Referring to FIG. 7, in the first discharge operation S200, the valves 452a, 454a, and 457a are opened, and the mixing member 455 forms a mixed solution by mixing the first treatment liquid and the second treatment liquid. The valve 456a is opened, and the nozzle 520 discharges the mixed liquid onto the substrate W through the first flow path 522. The substrate W is rotated by the support unit 430 together with or after the discharge of the mixed liquid, and a liquid film including the mixed liquid is formed on the substrate W. By mixing the first treatment liquid and the second treatment liquid in the separate mixing member 455 without providing a separate mixing space inside the nozzle 520, a problem caused by the mixed liquid remaining in the mixing space may be prevented.

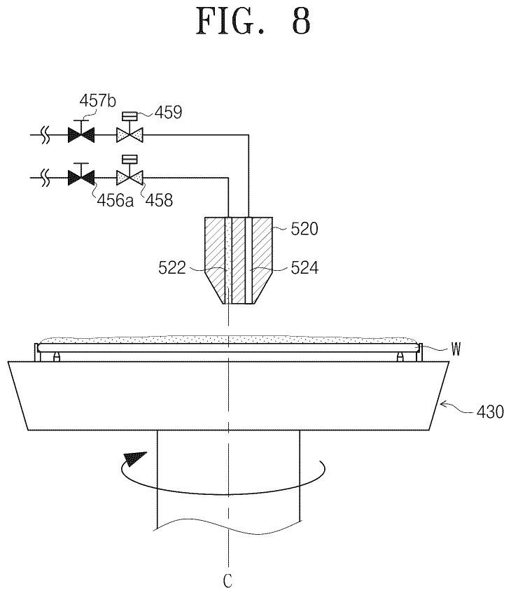

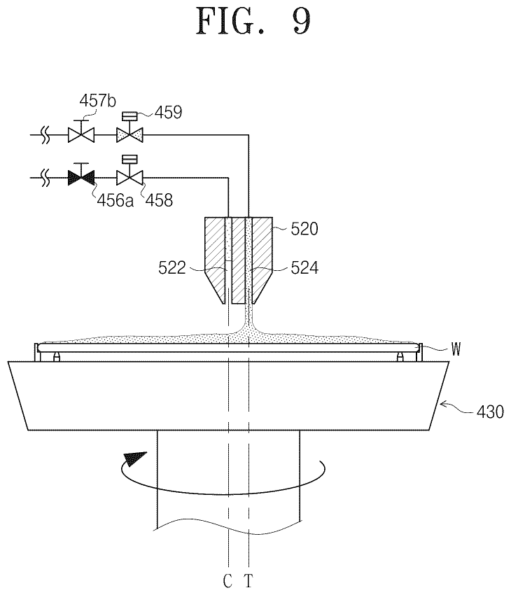

The second discharge operation S300 may be performed after the first discharge operation S200. FIG. 8 is a diagram schematically illustrating a stop operation in the second discharge operation of FIG. 5, and FIG. 9 is a diagram schematically illustrating a suck-back operation and a discharge operation in the second discharge operation of FIG. 5. Referring to FIGS. 8 and 9, in the second discharge operation S300, the valve 456a is closed, and the discharge of the mixed liquid is stopped. Thereafter, the first suck-back valve 458 may perform a suck-back operation of performing a suck-back operation on the first flow path 522. Accordingly, the mixed liquid remaining in the first flow path 522 may rise from the end of the nozzle, and the mixed liquid may be prevented from falling onto the substrate W. Furthermore, in the second discharge operation S300, the valves 457a and 457b are opened, and the nozzle 520 performs a discharge operation for discharging the second treatment liquid onto the substrate W. The second treatment liquid is discharged onto the substrate W through the second flow path 524. The discharged second treatment liquid replaces the mixed liquid. As a result, a liquid film composed of the second treatment liquid is formed on the substrate W. At the start of the discharge operation, an impact point T of the second treatment liquid is formed at a position spaced apart from the center C of the substrate. Thereafter, the impact point T of the second treatment liquid is moved to the center C of the substrate by the nozzle moving operation.

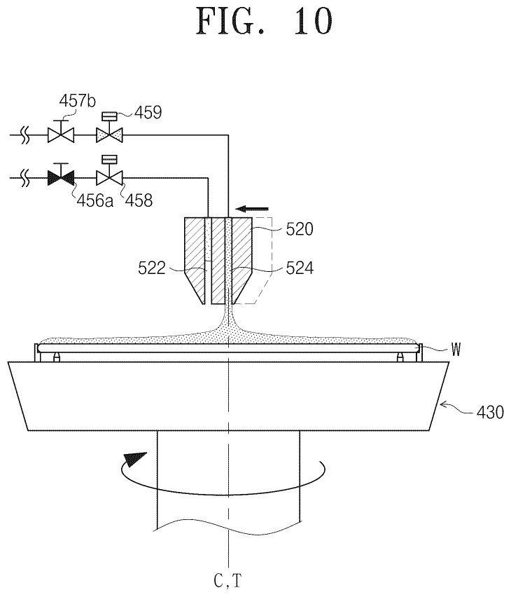

FIG. 10 is a diagram schematically illustrating a moving discharge operation and a fixed discharge operation in the second discharge operation. Referring to FIG. 10, the second discharge operation S300 includes a moving discharge operation S310 and a fixed discharge operation S330. When viewed from above, in the moving discharge operation S310, the nozzle 520 is moved so that the second flow path 524 coincides with the center C of the substrate. Accordingly, the impact point T of the second treatment liquid coincides with the center C of the substrate. In the second discharge operation S300, the suck-back operation, the discharge operation, and the moving discharge operation S310 may be performed simultaneously or sequentially.

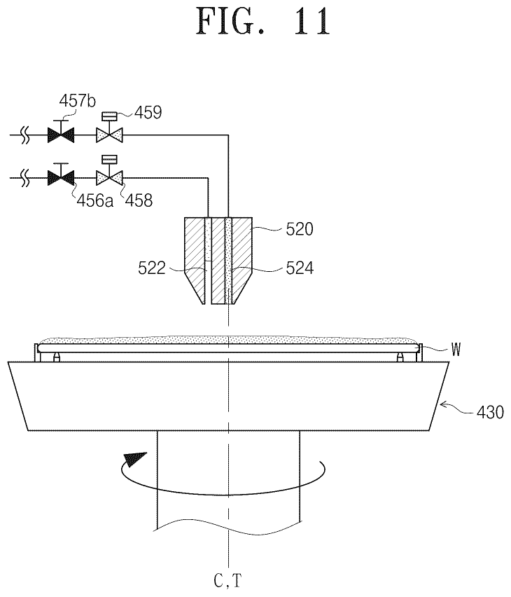

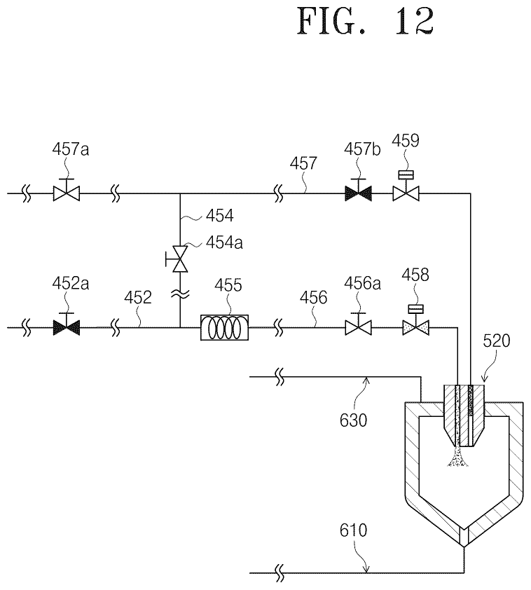

The cleaning operation S400 may be performed after the second discharge operation S300. The first flow path 522 is cleaned in the cleaning operation S400. FIG. 11 is a diagram schematically illustrating a stop operation in the cleaning operation of FIG. 5, and FIG. 12 is a diagram schematically illustrating a suck-back operation and a cleaning operation in the cleaning operation of FIG. 5. Referring to FIGS. 11 and 12, after the second discharge operation S300, the valve 457b is closed, the supply of the second treatment liquid to the second flow path 524 is stopped, and the discharge of the second treatment liquid is stopped. Thereafter, the second suck-back valve 459 sucks back the second flow path 524. Accordingly, the second treatment liquid is raised from the end of the nozzle. Thereby, it is possible to prevent the second treatment liquid remaining in the second flow path 524 from falling on the substrate W after the discharge of the second treatment liquid is stopped. The second flow path 524 is sucked back, the nozzle 520 is moved to the home port 600, and the first flow path 522 is cleaned. The valves 457a, 454a, and 456a are opened for cleaning of the first flow path 522, and the first suck-back valve 458 stops the suck-back operation. Thereby, the second treatment liquid is supplied to the first flow path 522 along the second treatment liquid mixing line 454, the mixing member 455, and the mixed liquid supply line 456. The nozzle 520 discharges the second treatment liquid through the first flow path 522 from the home port 600. Thereby, the second treatment liquid discharges the mixed liquid remaining in the first flow path 522 to the home port 600, and the first flow path 522 is cleaned by the second treatment liquid.

The first flow path 522 is sucked back by the first suck-back valve 458 to prevent the mixed liquid from falling, and accordingly, the mixed liquid remains in the first flow path 522. There is a problem that the temperature of the mixed liquid falls while the mixed liquid remains, and when the first discharge operation S100 is performed again, the temperature of the mixed liquid is not uniform. In the cleaning operation $400 according to the exemplary embodiment of the present invention, the mixed liquid remaining in the first flow path 522 is discharged to the outside of the nozzle 520. Accordingly, the temperature of the discharged mixed liquid may be maintained uniformly. In addition, contamination of the supply line by the remaining mixed solution may be prevented.

In the above-described example, the present invention has been described based on the case where the discharge of the second treatment liquid is stopped and the nozzle 520 is moved to the home port 600 and then the second flow path 524 is sucked back by the second suck-back valve 459 as an example. However, the present invention is not limited thereto, and the discharge of the second treatment liquid may be stopped and the second flow path 524 is sucked back by the second suck-back valve 459 and then the nozzle 520 may be moved to the home port 600.

In the above-described example, the present invention has been described based on the case where the second treatment liquid mixing line 454 is branched from the second treatment liquid supply line 457 as an example. However, the present invention is not limited thereto, and any configuration may be sufficient as long as the treatment liquid supply unit 450 may supply the first treatment liquid and the second treatment liquid to the mixing member 455 and supply the second treatment liquid to the nozzle unit 500.

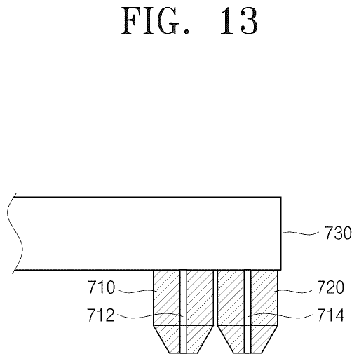

In addition, in the above-described example, the present invention has been described based on the case where the nozzle 520 is provided as a single nozzle and has the first flow path 522 and the second flow path 524 therein as an example. However, the present invention is not limited thereto, and as illustrated in FIG. 13, the first nozzle 710 having the first flow path 712 and the second nozzle 720 having the second flow path 714 may be provided to be supported by one arm 730.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A method of treating a substrate, the method comprising:
a nozzle moving operation of moving a nozzle unit having a first flow path and a second flow path to a top of a substrate;
a first discharge operation of, after the nozzle moving operation, discharging a first treatment liquid to the substrate through the first flow path; and
a second discharge operation of, after the first discharge operation, stopping the discharge of the first treatment liquid to the substrate through the first flow path, sucking back the first flow path, and simultaneously discharging a second treatment liquid to the substrate through the second flow path.

2. The method of claim 1, wherein in the first discharge operation, an impact point of the first treatment liquid is a center of the substrate, and
at a start of the second discharge operation, an impact point of the second treatment liquid is a position off the center of the substrate.

3. The method of claim 2, wherein the second discharge operation includes:
a moving discharge operation of discharging the second treatment liquid while moving the impact point of the second treatment liquid to the center of the substrate; and
a fixed discharge operation of discharging the second treatment liquid by fixing the impact point of the second treatment liquid to the center of the substrate after the moving discharge operation.

4. The method of claim 1, further comprising:
a cleaning operation of, after the second discharge operation, cleaning the first treatment liquid remaining in the first flow path.

5. The method of claim 4, wherein the cleaning operation includes supplying the cleaning solution to the first flow path in a state in which the second flow path is sucked back.

6. The method of claim 5, wherein the cleaning solution is the second treatment liquid.

7. The method of claim 6, wherein the first treatment liquid includes sulfuric acid, and
the second treatment liquid contains hydrogen peroxide solution.

8. The method of claim 4, wherein the cleaning operation is performed at a home port where the nozzle unit waits.

9. The method of claim 1, wherein the nozzle unit includes:
a first nozzle in which the first flow path is formed;
a second nozzle in which the second flow path is formed;
a nozzle arm equipped with the first nozzle and the second nozzle; and
an arm driver for moving the nozzle arm.

10. The method of claim 1, wherein the nozzle unit includes a single nozzle in which the first flow path and the second flow path are formed.

11-17. (canceled)

18. A method of treating a substrate, the method comprising:
a nozzle moving operation of moving a nozzle unit having a first flow path and a second flow path to a top of a substrate;
a first discharge operation of, after the nozzle moving operation, discharging a first treatment liquid in which sulfuric acid is mixed with hydrogen peroxide solution to the substrate through the first flow path;
a second discharge operation of, after the first discharge operation, stopping the discharge of the first treatment liquid to the substrate through the first flow path, sucking back the first flow path, and simultaneously discharging a second treatment liquid, which is hydrogen peroxide solution, to the substrate through the second flow path; and
a cleaning operation of, after the second discharge operation, cleaning the first treatment liquid remaining in the first flow path,
in the first discharge operation, an impact point of the first treatment liquid is a center of the substrate, and
at a start of the second discharge operation, an impact point of the second treatment liquid is a position off the center of the substrate, and
the second discharge operation includes:
a moving discharge operation of discharging the second treatment liquid while moving the impact point of the second treatment liquid to the center of the substrate; and
a fixed discharge operation of discharging the second treatment liquid by fixing the impact point of the second treatment liquid to the center of the substrate after the moving discharge operation.

19. The method of claim 18, wherein the cleaning operation includes discharging the second treatment liquid through the first flow path in a state where the nozzle unit is moved to a waiting home port, and the second flow path is sucked back.

20. The method of claim 19, wherein the nozzle unit includes a single nozzle in which the first flow path and the second flow path are formed.
